(19) United States
(12) Patent Application Publication
(10) Pub. No.: US 2002/0174825 A1
(43) Pub. Date: Nov. 28, 2002

(54) Method of growing oriented single crystals with reuseable crystal seeds or crystal nuclei

(76) Inventor: Gunther Wehrhan, Jena (DE)

Correspondence Address: STRIKER, STRIKER & STENBY, 103 East Neck Road, Huntington, NY, 11743, US

(21) Appl. No.: 10/151,422

(22) Filed: May 20, 2002

(30) Foreign Application Priority Data
May 18, 2001 (DE) 101 24 423.1

(51) Int. Cl. C30B 11/00; C30B 1/00; C30B 17/00; C30B 28/06; C30B 21/02; C30B 9/00

(52) U.S. Cl. 117/81; 117/904; 117/83

(57) ABSTRACT

The method for manufacture of especially large-volume single crystals of uniform orientation includes growing the single crystals with the help of a crystal seed. The method includes producing or introducing a melt of crystal raw material into a melt vessel with a vessel cross-section determined by a bottom and a wall of the melt vessel, arranging the crystal seed on the bottom of the melt vessel with an orientation of the single crystal to be grown and then slowly cooling the melt to or below a melting point of the crystal raw material, starting from a surface of the crystal seed, so that the single crystal is grown with the uniform orientation. A part of an already grown single crystal is cut off to form the crystal seed with a dimension that entirely covers the vessel cross-section at the bottom of the melt vessel. This sort of single crystal is useful for making lenses, prisms, light conducting rods, optical windows and optical components for DUV photolithography, steppers, excimer lasers, wafers, computer chips, integrated circuits and electronic devices containing them.

### BACKGROUND OF THE INVENTION

1. The Field of the Invention

The present invention relates to a method of growing especially large-volume single crystals from a melt with a uniform orientation along a desired growth direction and to the uses of these single crystals made by the method.

2. Description of the Related Art

Single crystals are characterized by having a uniform orientation over their entire volume. That means that the entire crystal volume has a high optical homogeneity. For this reason they are outstandingly suited for use in the optics industry or as starting material for optical components in DUV photolithography, for example for steppers or excimer lasers.

Growth of single crystals from the melt is known. Greatly varying methods for crystal growth are described in textbooks for crystal growth, such as the 1088 page work, “Crystal Growth”, by K. -Th. Wilke and J. Bohm, Principally crystals can be grown from the gas phase, from the melt, from solution or even from the solid phase by recrystallization or diffusion through the solid phase. These methods however are chiefly for the laboratory and not for industrial production.

Oriented large-volume single crystals in spite of all usually have no homogeneous optical and mechanical properties. Crystals of this type with a suitable crystal orientation are highly desirable for commercial purposes. There are special problems encountered in the manufacture of large-volume single crystals, since they spontaneously change their orientation, i.e. the positions of their crystal axes, during growth. This leads to optically nonuniform crystals, in which the index of refraction is not the same in all regions.

Currently it has been possible to make some crystals, which have these desirable properties. However up to now it has not been possible to make large-volume crystals, which have no faults, which are highly optically uniform and which are not colored when irradiated with an intense radiation source.

In the currently known procedure, for example, in the manufacture of large calcium fluoride single crystals, each crystal grows in the direction of the {1,1,1} axes. However the yield of these single crystals was found to be very small, i.e. large crystals of a satisfactory size amount to about 6 to 8 percent of the grown material. Since a crystal growth process lasts about six weeks and the number of growth units required for crystal growth is limited, up to now large-volume uniform single crystals cannot be manufactured in the quantity, in which they are required.

Furthermore currently it has not been possible to grow large-volume crystals, i.e. round crystals with a diameter of greater than 200 mm and a height of greater than 100 mm, since faults are usually formed in crystals of those dimensions, i.e. a reorientation or disorientation of crystal axes occurs.

It has already been attempted to grow single crystals that are in the form of plates. EP-A 0 338 411 describes an apparatus and method for controlled growth of large single crystals in a plate-shape from a melt, in which the melt vessel has a rectangular cross-section. The resulting plate-shaped single crystals have two comparatively wide and two comparatively narrow sides. In this apparatus for crystal growth heating devices are arranged along the wide sides of the crystal material. After melting the crystal material the melt vessel is slowly drawn from the heating units by means for a drawing device, whereby its contents are cooled and then crystallize. With this method it is of course possible to grow large oriented crystal plates. However they do not have a sufficient extent in all three spatial directions for many purposes.

Furthermore it has not been possible up to now to form large highly optically homogeneous crystals in a satisfactory manner, i.e. so that the index of refraction is the same in all directions.

Attempts have been made to allow the crystal to grow in a liquid phase so that its entire crystal volume has a uniform crystal orientation, i.e. so that a so-called block formation, also formation of different crystal orientations, is avoided. That has been achieved according to the state of the art by placing a smaller single crystal, a so-called seed crystal or crystal nucleus, in a cavity in a melt vessel, a so-called crystal pocket. The seed crystal or crystal nucleus is placed at the position in the vessel, from which crystallization begins.

So that this type of crystal seed is not prematurely melted, it must be protected from the temperatures existing in the melt vessel. This occurs usually by cooling water supplied through a metal pipe, which is arranged under the seed pocket. The cooling pipe is mounted in the crystallization apparatus so that it is movable, whereby the cooling is controllable. Thus the cooling power can be increased when it is too weak or decreased when it is too strong. This method has the disadvantage that the cooling power and thus the temperature of the seed pocket can only be controlled with difficulty. This has the consequence that the crystal seed is very easily completely melted in the melt, whereby the desired orientation is lost. Furthermore the large temperature differences arising in cooling lead to high material stresses, which lead to rapid destruction of the cooling device and thus to a shortened service life of the crystal growth unit.

Other ways to dissipate the heat in the melt vessel bottom have been tried. For example, DE-A 24 61 553 describes cooling by means of a pipe or duct arranged under the conical bottom of the melt and/or growth vessel, which is cooled by means of helium. Furthermore the use of a cooling gas or water for cooling the seed pocket has the disadvantage that the water-sensitive crystal and thus the entire arrangement would be destroyed if there is a leak. Also moisture collects on the entire apparatus, which is not removable without more.

It has been shown however that the crystal obtained at the conclusion of this process using the seed crystal no longer has the desired orientation in the initial growing direction.

In spite of all these improvements, which have been achieved in the above-described methods, crystals are frequently still obtained, whose optical properties are not satisfactory, i.e. that do not have tolerable optical inhomogeneities.

### SUMMARY OF THE INVENTION

Since a growth process of this type lasts over several weeks and the orientation of the crystal obtained is only established at the end of the growth process, it is an object of the present invention to increase the yield of single crystals with the desired predetermined orientation and to avoid optical inhomogeneities and thus to reduce the loss of expensive crystal raw material.

It is also an object of the present invention to provide a method of making a large-volume single crystal with an arbitrary predetermined or desired orientation along its {h,k,l} axes, preferably in the {1,1,1} or {1,1,2} orientation, in a satisfactory yield.

It is another object of the present invention to shorten the time required to grow a large-volume single crystal with a uniform predetermined orientation.

The method of making a single crystal with a uniform orientation according to the invention includes the steps of:

a) producing or introducing a melt of crystal raw material in a melt vessel with a vessel cross-section determined by its bottom and its wall;

b) cutting off a part of an already grown single crystal to form a crystal seed having dimensions so that the crystal seed completely covers a vessel cross-section of the melt vessel when the crystal seed is arranged on the bottom of the melt vessel;

c) arranging the crystal seed on the bottom of the melt vessel so that the crystal seed has an orientation of the single crystal to be grown; and then

d) slowly cooling the melt to or below a melting point of the crystal raw material, starting from a surface of the crystal seed, so that the single crystal with the uniform orientation is grown.

It was surprisingly found that the orientation of the single crystal grown from a crystal seed conforms sufficiently to the orientation of the crystal seed, when a super seed or super nucleus is used instead of a smaller crystal seed arranged in a seed pocket. The super seed or super nucleus has been already grown prior to growth of the crystal to be grown, or is pre-grown, and has the extent or dimension of the crystal to be grown. Usually a separate piece of an already grown crystal is used as the super seed. These pieces are automatically obtained by cutting a grown single crystal along a horizontal cross-section of it during manufacture. Up to now these pieces were thrown out without adequate consideration. The crystal seed used according to the invention is thus large enough so that it covers the entire cross-section of the melt vessel. The inner wall and bottom of the melt and/or growth vessel define the outer dimensions of the single crystal to be grown, i.e. its base area, cross-sectional surface area and height. The maximum height of the crystal to be grown corresponds to the interior height of the melt vessel.

This type of super seed according to the invention is usually obtained by cutting off the lower part of an already grown large-volume crystal. The upper part of the crystal is further processed, especially for lenses. The cut off lower part is used as a super seed in the melt and/or growth vessel and is used there as a new seed adapted already to the dimension and shape of the vessel. In this way a considerable portion of the crystal raw material is reused. Since the lower parts of homogeneous single crystals are cut off according to the invention to form the crystal seeds, the laborious growing of the single crystal a crystal orientation transferred from a small crystal seed in a crystal seed pocket with controlled cooling can be dispensed with. According to the invention of course a single crystal, which has the desired properties in regard to orientation and stress homogeneity, can be cut along cross-sectional surfaces lying over each other to form a single crystal piece. The resulting single crystal piece can be used as a reusable crystal seed or seed crystal. Thus one grown single crystal can provided a number of different crystal seeds.

In the method according to the invention only especially good single crystals are employed. They may be measured by means of known methods. Since they are already available as “waste” from crystal manufacturing processes, their quality can be quickly and simply established by means of known measuring methods. Such single crystals are used according to the invention, which are free of grain boundaries and which have very highly uniform stress properties, i.e. they are substantially stress-free. The term “grain-boundary-free” means that the crystalline regions present in the crystal are preferably not tilted about an angle relative to each other, which exceeds 5 minutes. The methods according to the invention are used preferably in a uniformly strained or stressed crystal, in which the light waves are shifted no more than 10 nm/cm in all cross-sectional areas and in all directions. These types of stress measurements may be performed, for example, so that a crystal is measured between polarization filters or, for example, by means of an interferometer. These methods are well known to those skilled in the art. They are described briefly in DE-A 101 11 450.

It has been shown that the transfer of the crystal orientation from the seed to the solidifying melt by reuse, i.e. the recycling of already formed single crystal pieces, which have the same cross-sectional dimensions as the crystal to be grown, is especially successful. These large-size single crystals are obtained especially by cleavage of an already grown single crystal having a high homogeneity. This crystal grows upward in a still more or less cylindrical shape with very few crystal faults when this super seed is used. Of course it is also possible to use melt and/or growth vessels with non-cylindrical walls, for example gently inclined walls, such as pyramidal-conical walls, for special cases in the method for growing crystals according to the invention. This sort of recycled super seed is tested prior to its further use for orientation and homogeneity and is subsequently used for crystal growth. The use of already grown crystal material selected for its higher purity in the form of a purified cleaved piece has proven to be especially suitable for manufacture of this sort of super seed. In this way it is possible to detect crystal faults occurring at this stage and to cut out particularly critical regions from the conventional growth process. Thus it is no longer necessary to wait until the entire crystal is made, in order to establish whether or not nonuniformities are arising the growth process. Since the growth of this regions amounts to 40 to 60% of the growing time, the entire growth process can be correspondingly reduced.

The laborious control of the inoculation of a small crystal seed to form a large single crystal can be avoided or dispensed with, so that the entire apparatus, for example the seed pocket cooling, can be simplified in this way. The manufacture and the operation of this apparatus is thus essentially more economical.

Furthermore the growth process according to the invention can be performed without expensive measuring techniques. The crystal growth process can be started at a predetermined location without the effort of measuring or determining the location of the phase boundary between liquid and solid. It is also possible to melt the super seed at the bottom of the growth and/or melt vessel to a predetermined level, usually at least 2 mm, at the same time as melting the crystal raw material. In that way the new crystal growth process starts from the newly formed boundary surface between the oriented super seed and the melt, without an increase in the cross-section of the crystal during growth.

The crystal raw material used in the method according to the invention process includes especially raw material, which contains scavenger material besides crystal material, which reacts with the impurities to form volatile substances. Preferred crystal materials include MgF₂, BaF₂, SrF₂, LiF and NaF. CaF₂ is especially preferred. Large-volume single crystals are obtained in process according to the invention, which have a diameter of at least 200 mm, preferably at least 250 mm, and especially preferably a diameter of at least 300 mm. They have a height of at least 100 mm, preferably 130 mm, and especially preferably at least 140 mm. The usual height for the large-volume single crystals made by the growth method according to the invention is at least 200 mm and especially at least 300 mm. The optical homogeneity thereby obtained over the entire crystal volume is thus extremely great. That is, the maximum change of the index of refraction over the entire crystal amounts to a maximum difference of δn ≦3×10⁻⁶, preferably ≦2×10⁻⁶, and especially preferably ≦1×10⁻⁶. The strain birefringence SDB <3 nm/cm, preferably <2 nm/cm, and especially preferably <1 nm/cm.

The method according to the invention is preferably preformed in a vacuum between 10⁻³ and 10⁻⁶ mbar (corresponding to 10⁻¹ to 10⁻⁴ Pa), and even more preferably between 10⁻⁴ and 10⁻⁵ mbar (corresponding to 10⁻² to 10⁻³ Pa). It is particularly preferred that the method according to the invention is performed in a protective gas atmosphere, especially a non-oxidizing atmosphere. The entire apparatus according to the invention is rinsed with an inert gas atmosphere or an inert gas mixture prior to or during the heating.

The large-volume crystals obtained by the method according to the invention are suitable for the DUV lithography and for making wafers coated with a photo lacquer and thus for making of electronic units. The large-volume crystals made by the method according to the invention, or with the apparatus according to the invention, are suitable for making lenses, prisms, light guide rods, fiber optic cables, optical windows and optical devices for DUV lithograph. They are especially useful for making steppers and excimer lasers, and thus also for making integrated circuits as well as other electronic devices, such as computer chips containing processors and other electronic devices, which contain chip-like integrated circuits.

### BRIEF DESCRIPTION OF THE SEVERAL VIEWS OF THE DRAWING

The objects, features and advantages of the invention will now be described in more detail with the aid of the following description of the preferred embodiments, with reference to the accompanying figures in which:

FIG. 1 is a diagrammatic cross-sectional view through a melt and/or growth vessel with a seed pocket according to the prior art;

FIG. 2 is a diagrammatic cross-sectional view through a melt vessel according to the state of the art, but containing a super crystal seed according to the invention;

FIG. 3 is a diagrammatic cross-sectional view through a melt vessel with a flat bottom and containing a super crystal seed according to the invention; and

FIG. 4 is a diagrammatic cross-sectional view of a large-volume single crystal with suspended super crystal seed according to the invention.

### DETAILED DESCRIPTION OF THE INVENTION

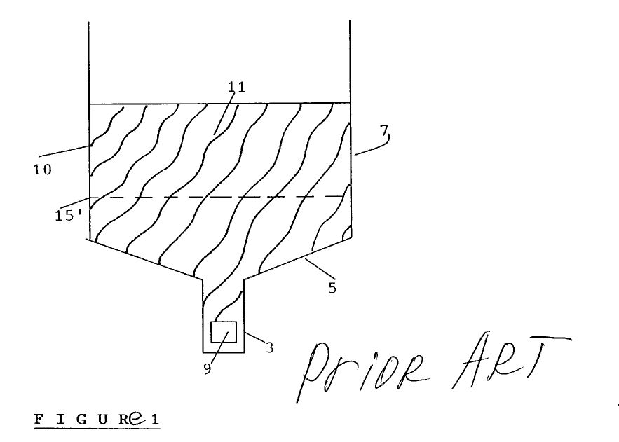

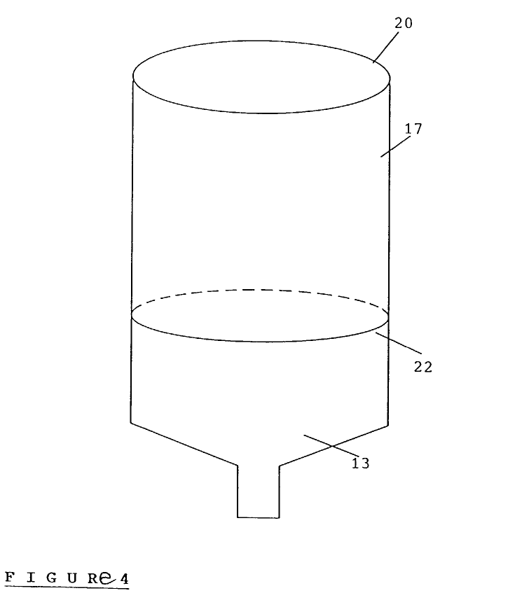

FIG. 1 shows a melt vessel 10 according to the state of the art, which has a cylindrical sidewall 7, a conical or cone-shaped bottom 5 with a seed pocket 3 arranged at the cone peak. The melt vessel 10 contains a crystal seed 9 in the seed pocket 3 and powdery crystal raw material 11 arranged above it. According to the state of the art, as described in DE-24 61 553, the melting crystal raw material in the melt vessel defined by the sidewall 7 and the bottom 5 reaches the crystal seed 9, slowly traveling downward from above it. Thus the crystal seed 9 is melted on its upper side facing the melt, whereby a phase boundary surface between solid and liquid arises, whose solid phase constitutes the crystal seed arranged in the desired orientation. The crystal seed slowly grows further upward into the melt by slowly cooling the melt starting from the seed pocket 3. The crystal seed 9 then grows further beyond the end of the seed pocket 3 into the melt vessel 10 above the conical or cone-like bottom 5. Because of that the crystal seed 9 not only grows upward, but also further to the side, until it completely covers the cone-shaped bottom 5 and reaches the cylindrical sidewall 7. From this point the crystal only grows cylindrically upward further until the entire melt above it has crystallized. After the crystal has been formed it is slowly cooled until it is at room temperature and then is removed from the melt and/or growth vessel 10. In this way a single crystal may be made, as shown for example in FIG. 4.

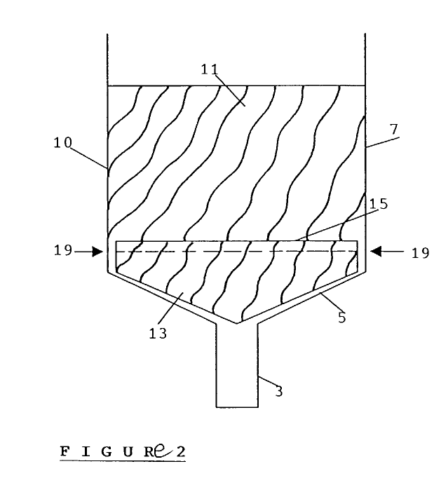

FIG. 2 shows a melt or growth vessel 10 according to the prior art, as described in FIG. 1. However this contains a super crystal seed 13 according to the invention, which covers the entire bottom 5 of the melt vessel 10. The super crystal seed 13 has a shape that is adapted to the cone-shaped or conical bottom 5 and the cylindrical sidewall 7. Thus it fills the bottom region of the melt vessel completely. Preferably however the super crystal seed 13 has a slightly smaller dimension at the sidewall 7, so that an expansion gap required for thermal expansion arises between the super crystal seed 13 and the sidewall 7. The crystal raw material is arranged above it. To make the large-volume oriented single crystal the crystal raw material 11 is melted, preferably starting from above, and of course until the surface 15 of the super crystal seed is reached. After that the super crystal seed 13 is melted until at a preferably predetermined height 19. As soon as this time point has been reached, further heating does not take place, but the melt is slowly cooled, whereby the crystal super seed 13 grows vertically upward along the sidewall 7 in a cylindrical shape from the surface defined by the height 19. The growth of the crystal super seed in this way takes place without a significant widening or reduction of the crystal cross-section. As soon as the crystal growth ends, the single crystal so obtained, as described in FIG. 1, is slowly and cautiously cooled according to the prior art.

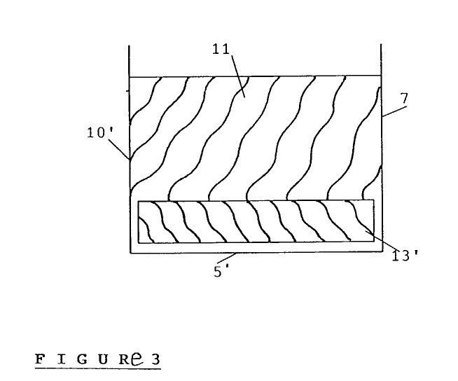

FIG. 3 shows a simplified melt and/or crystal growth vessel 10′, which has a planar bottom 5′ instead of the cone shaped bottom 5. The method according to the invention can be performed with this melt vessel 10′ having the flat bottom 5′. Since the crystal seed pocket 3 is eliminated and the bottom is not conical, it is no longer possible to use the super crystal seed 13 according to FIG. 2 in this melt vessel 10′. However a super crystal seed 13′, which has a flat bottom can be used. This sort of melt vessel is significantly easier to make and to operate. A super seed crystal 13′ is arranged in the vessel bottom of this melt vessel 10′ and may be obtained by cutting a large-volume single crystal 20, as is shown in FIG. 4. The large-volume single crystal 20 of FIG. 4 comprises the crystal 17 above the cut surface 22, which can be used later in the optical industry and the lower part cut from it, which can be used as a new super crystal seed 13. Understandably it is also possible to make a super seed according to the procedure of FIG. 1, in which only so much crystal raw material is filled in, so that the dashed line 15′ in FIG. 1 is reached. The procedure for making this type of super crystal seed corresponds to that described in FIG. 1.

The disclosure in German Patent Application 101 24 423.1 of May 18, 2001 is incorporated here by reference. This German Patent Application describes the invention described hereinabove and claimed in the claims appended hereinbelow and provides the basis for a claim of priority for the instant invention under 35 U.S.C. 119.

While the invention has been illustrated and described as embodied in a method of growing oriented single crystals with reusable crystal nuclei, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

I claim:

1. A method of making a single crystal with a uniform orientation, said method comprising the steps of:
a) producing or introducing a melt of crystal raw material in a melt vessel with a vessel cross-section determined by a bottom and a wall of said melt vessel;
b) cutting off a part of an already grown single crystal to form a crystal seed having dimensions such that said crystal seed completely covers said vessel cross-section when said crystal seed is arranged on the bottom of the melt vessel;
c) arranging the crystal seed on the bottom of the melt vessel so that the crystal seed has an orientation of the single crystal to be grown; and then
d) slowly cooling the melt to or below a melting point of the crystal raw material, starting from a surface of the crystal seed, so that the single crystal with the uniform orientation is grown from the crystal seed.

2. The method as defined in claim 1, wherein said melt vessel is round or has a circular cross-section.

3. The method as defined in claim 1, wherein said crystal seed is reusable.

4. The method as defined in claim 1, 2 or 3, wherein said crystal raw material is calcium fluoride.

5. The method as defined in claim 1, 2 or 3, wherein said part of said already grown single crystal is a lower part of an already grown single crystal.

6. The method as defined in claim 1, 2 or 3, wherein the crystal seed is a super seed comprising a cleaved piece of the crystal raw material and said cleaved piece is obtained from a previous crystal growth process.

7. The method as defined in claim 1, wherein said wall of said melt vessel is a cylindrical sidewall.

8. The method as defined in claim 1, wherein said bottom of said melt vessel is conical.

9. The method as defined in claim 1, wherein said bottom of said melt vessel is flat or planar.

10. The method as defined in claim 1, 2 or 3, wherein said method is performed in a vacuum between 10⁻³ and 10⁻⁶ mbar or under a protective atmosphere, said protective atmosphere comprising at least one inert gas.

11. The method as defined in claim 1, 2 or 3, wherein said crystal raw material is selected from the group consisting of CaF₂, BaF₂, SrF₂, LiF and NaF.

12. The method as defined in claim 1, 2 or 3, wherein said single crystal grown by the method has a diameter of at least 200 mm, a height of at least 200 mm, a maximum variation of index of refraction of less than or equal to 3×10⁻⁶ and a strain birefringence of less than 3 nm/cm.

13. A single crystal for the manufacture of lenses, prisms, light conducting rods, optical windows and optical components for DUV photolithography, steppers, excimer lasers, wafers, computer chips, integrated circuits and electronic devices containing said chips and said integrated circuits, said single crystal being made by a method comprising producing or introducing a melt of crystal raw material in a melt vessel with a vessel cross-section determined by a bottom and a wall of said melt vessel; cutting off a part of an already grown single crystal to form a crystal seed having dimensions such that said seed crystal completely covers the vessel cross-section when the crystal seed is arranged on the bottom of the melt vessel; arranging the crystal seed on the bottom of the melt vessel so that the crystal seed has an orientation of the single crystal to be grown; and then slowly cooling the melt to or below a melting point of the crystal raw material, starting from a surface of the crystal seed, so that the single crystal with the uniform orientation is grown.

14. The single crystal as defined in claim 13, wherein said melt vessel has a round cross-section or a circular cross-section.

15. The single crystal as defined in claim 14, wherein said melt vessel has a cylindrical sidewall.

16. The single crystal as defined in claim 13, wherein said bottom of said melt vessel is conical or flat.

17. The single crystal as defined in claim 13, 14, 15 or 16, wherein said crystal seed is reusable.

18. The single crystal as defined in claim 13, wherein said crystal raw material is calcium fluoride.

19. The single crystal as defined in claim 13, 14, 15 or 16, wherein said part of said already grown single crystal is a lower part of an already grown single crystal.

20. The single crystal as defined in claim 13, 14, 15 or 16, wherein the crystal seed is a super seed comprising a cleaved piece of the crystal raw material and said cleaved piece is obtained from a previous crystal growth process.

21. The single crystal as defined in claim 13, 14, 15 or 16, wherein said method is performed in a vacuum between 10⁻³ and 10⁻⁶ mbar or under a protective atmosphere, said protective atmosphere comprising at least one inert gas.

22. The single crystal as defined in claim 13, 14, 15 or 16, wherein said crystal raw material is selected from the group consisting of CaF₂, BaF₂, SrF₂, LiF and NaF.

23. The single crystal as defined in claim 13, 14, 15 or 16, having a diameter of at least 200 mm, a height of at least 200 mm, a maximum variation of index of refraction of less than or equal to 3×10⁻⁶ and a strain birefringence of less than 3 nm/cm.
